(19) United States
(12) Patent Application Publication
(10) Pub. No.: US 2011/0069849 A1
(43) Pub. Date: Mar. 24, 2011

(54) Portable Amplifier

(76) Inventor: Richard Borden, Seminole, FL (US)

(21) Appl. No.: 12/562,193

(22) Filed: Sep. 18, 2009

(51) Int. Cl. H03F 99/00

(52) U.S. Cl. 381/120

(57) ABSTRACT

A portable amplifier for use with electric guitars and other audio output sources. The amplifier comprises a housing, which houses components required for a portable amplifier, including a power source, at least one speaker and a male input plug that can be extended or retracted into the body of the housing. In one embodiment, the male input plug can be positioned in a plurality of orientations for insertion into musical instruments.

This application includes material which is subject to copyright protection. The copyright owner has no objection to the facsimile reproduction by anyone of the patent disclosure, as it appears in the Patent and Trademark Office files or records, but otherwise reserves all copyright rights whatsoever.

### FIELD OF THE INVENTION

The present invention relates to amplifiers used with musical instruments, and more particularly to portable amplifiers used with electric guitars and similar musical instruments.

### SUMMARY OF THE INVENTION

In one embodiment, the invention is a portable amplifier for use with electric guitars and other audio output sources. The amplifier comprises a housing, which houses components required for a portable amplifier, including a power source, at least one speaker and a male input plug that can be extended or retracted into the body of the housing. In one embodiment, the male input plug can be positioned in a plurality of orientations for insertion into musical instruments.

### BRIEF DESCRIPTION OF THE DRAWINGS

The foregoing and other objects, features, and advantages of the invention will be apparent from the following more particular description of preferred embodiments as illustrated in the accompanying drawings, in which reference characters refer to the same parts throughout the various views. The drawings are not necessarily to scale, emphasis instead being placed upon illustrating principles of the invention.

FIG. 1 illustrates a front view of one embodiment of a portable amplifier with male input plug extended.

FIG. 2 illustrates a left side view of one embodiment of a portable amplifier with male input plug retracted.

FIG. 3 illustrates a left side view of one embodiment of a portable amplifier with male input plug retracted.

FIG. 4 illustrates a rear view of one embodiment of a portable amplifier with male input plug retracted.

FIG. 5 illustrates a cutaway view of one embodiment of a portable amplifier without male input inserted.

FIG. 6 illustrates a perspective view of a male plug with 3 electrical contacts.

FIG. 7 illustrates how the male plug of at least one embodiment of the present invention can be positioned in at least three orientations when inserted into an electric guitar.

### DETAILED DESCRIPTION

The present invention is generally directed to a portable amplifier for use with electric guitars and other musical instruments that plug into amplifiers. In at least one embodiment of the present invention, the amplifier is a small, lightweight, battery powered device with a male plug that can be extended or retracted into the body of the device.

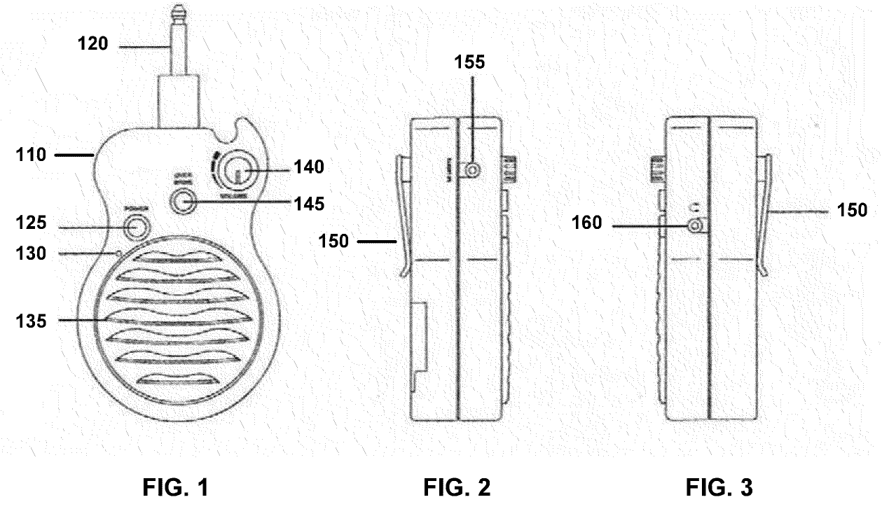

FIG. 1 illustrates a front view of one embodiment of a portable amplifier with male input plug extended.

The amplifier has a housing 110 which may be constructed of any suitable material, such as plastic. Extending from the housing is an adjustable male input plug 120. In at least one embodiment, the plug is a three way male input plug. In one embodiment, the plug 120 is mounted in the housing such that it can be extended or retracted by pivoting the plug into or out of the housing.

In one embodiment, the amplifier has a power on/off switch 125 and a power indicator 130. The amplifier has at least one speaker 135 mounted within the housing 110. In one embodiment, the speaker is a 4-OHM 1W speaker. Volume can be controlled by a master volume control 140 and there is an overdrive on/off switch

FIG. 2 illustrates a left side view of one embodiment of a portable amplifier with male input plug retracted.

In one embodiment, the amplifier has a belt clip 150 removably attached to the back of the housing 110. The amplifier has an audio input jack 155 that can receive the male connector of an audio input source such as an MP3 player or any other audio source adapted to have a male output plug.

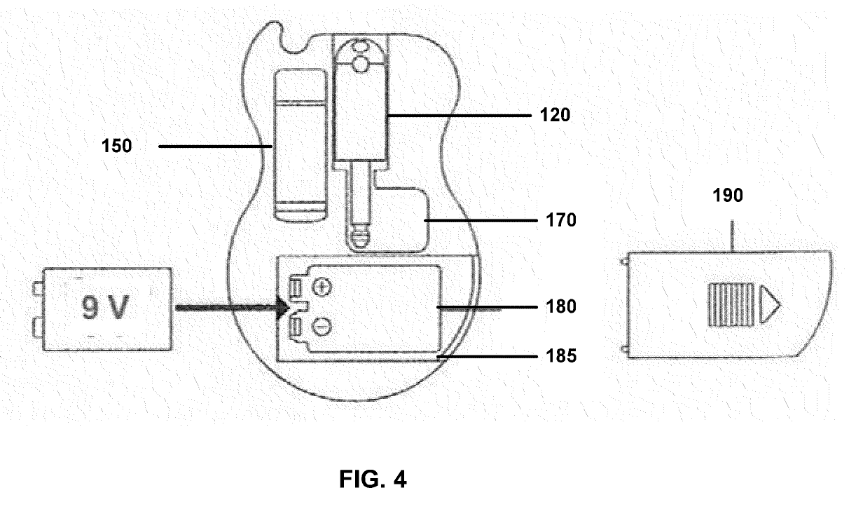

FIG. 3 illustrates a left side view of one embodiment of a portable amplifier with male input plug retracted.

In one embodiment, the amplifier provides a headphone jack 160 for headphones or any other audio presentation device adapted to have a male input plug.

FIG. 4 illustrates a rear view of one embodiment of a portable amplifier with male input plug retracted.

The male input plug 120 has been pivoted into a “J” shaped socket 170 in the housing 110. In one embodiment, the socket is “J” shaped to allow a user to easily access the male plug 120 in its retracted position. The belt clip 150 is to the side of the socket 170 so as not to interfere with the movement of the male input plug 120. In one embodiment, the amplifier is powered by a battery 180 inserted into a battery socket 185, which is covered by a removable cover 190. In one embodiment, the battery 180 is a conventional 9V battery, however any suitable battery could be used.

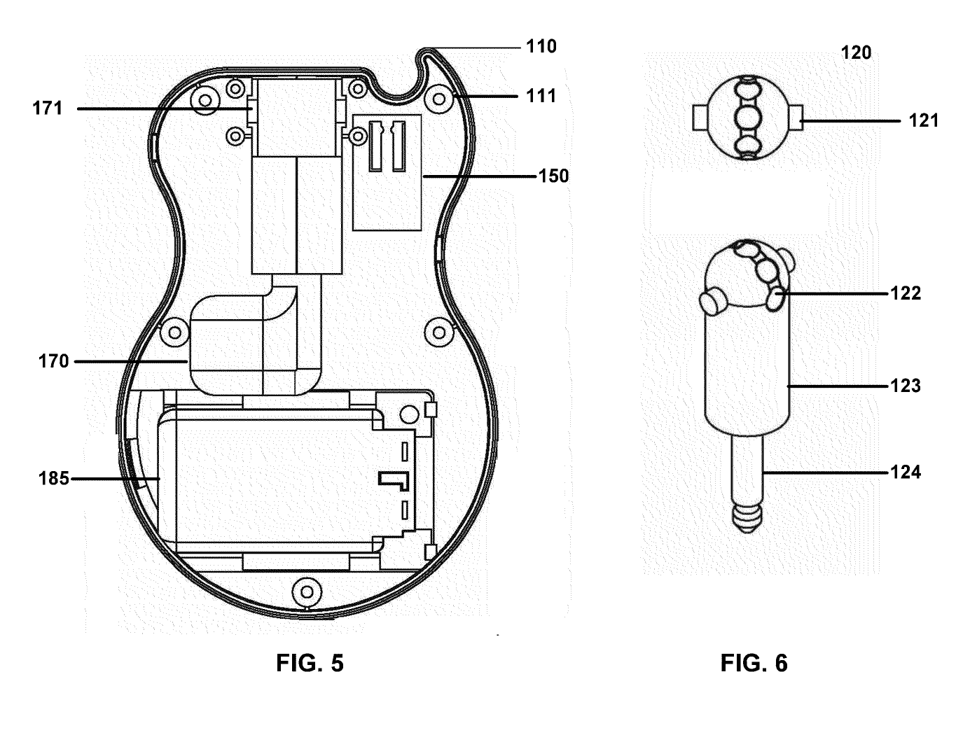

FIG. 5 illustrates a cutaway view of one embodiment of a portable amplifier without male input inserted.

This figure shows how the socket 170 in the housing 110 can provide hinge insertion points 171 for the male input plug 120. In one embodiment, the body of the housing may be constructed of at least two halves joined at points 111 by, for example, screws. The figure additionally shows cutaway views of the socket for the male plug 120 and the battery socket 185.

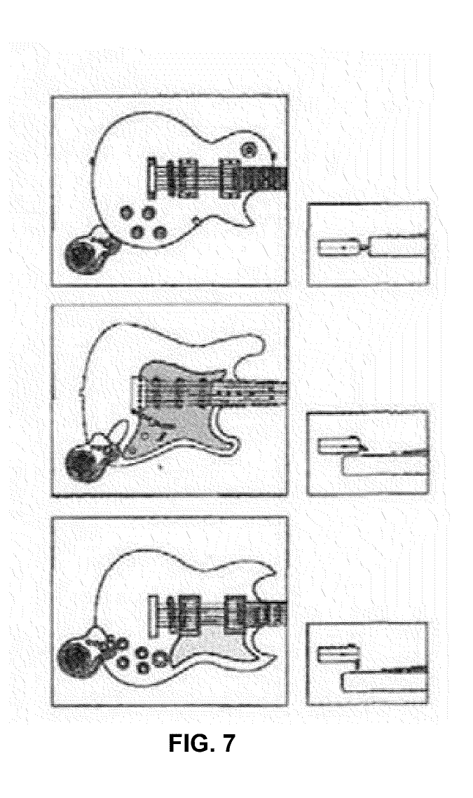

FIG. 6 illustrates a perspective view of a male plug with 3 electrical contacts.

This figure shows how the male plug 120 can have hinges or pivot points 121 which socket 170 in the housing 110 can provide hinge insertion points 171 which can be inserted into hinge insertion points 171 such that the plug is mounted in the amplifier such that it can freely rotate about the hinge 121. In one embodiment, the plug 121 has a body 123, a male connector 124 and three electrical contact points 122. The three electrical contact points 122 allow the male plug to be positioned in three distinct positions when the amplifier is inserted into, for example, a guitar. The plug could be constructed to have more or less contact points, for example, 1, 2 or 4, supporting a corresponding number of positions or orientations of the plug.

FIG. 7 illustrates how the male plug of at least one embodiment of the present invention can be positioned in at least three orientations when inserted into an electric guitar.

While various embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure.

I claim:

1. A portable amplifier comprising:
a housing;
a power source mounted within the housing;
a speaker mounted within the housing;
a male input plug pivotably mounted within the housing such that the male input plug can be pivoted into and out of the housing and wherein the male plug can be positioned in a plurality of orientations when it is inserted into a female connector of a musical instrument.
